(19) United States
(12) Patent Application Publication
(10) Pub. No.: US 2013/0292057 A1
(43) Pub. Date: Nov. 7, 2013

(54) CAPACITIVELY COUPLED PLASMA SOURCE WITH RF COUPLED GROUNDED ELECTRODE

(71) Applicant: APPLIED MATERIALS, INC., Santa Clara, CA (US)

(72) Inventors: Kartik Ramaswamy, San Jose, CA (US); Steven Lane, Porterville, CA (US)

(21) Appl. No.: 13/632,322

(22) Filed: Oct. 1, 2012

Related U.S. Application Data
(60) Provisional application No. 61/638,855, filed on Apr. 26, 2012.

(51) Int. Cl. H01L 21/77

(52) U.S. Cl. CPC H01L 21/77
USPC 156/345.44; 118/723 E

(57) ABSTRACT

An overhead RF coupling chamber couples RF power to a ceiling electrode of a plasma reactor chamber, the RF coupling chamber having a resonant annular volume defined by coaxial cylindrical conductors, one of which is coupled to an RF power source, the chamber ceiling having an annular gap around the electrode, and the resonant annular volume being aligned with the annular gap so that the resonant annular volume opens into the interior of the main chamber, thereby enhancing the electrical length of the RF coupling chamber.

CROSS-REFERENCE TO RELATED APPLICATIONS

This application claims the benefit of U.S. Provisional Application Ser. No. 61/638,855, filed Apr. 26, 2012 entitled CAPACITIVELY COUPLED PLASMA SOURCE WITH RF COUPLED GROUNDED ELECTRODE, by Kartik Ramaswamy, et al.

### BACKGROUND

The recent growth in the size semiconductor wafers in integrated circuit fabrication is making it more difficult to obtain the needed degree of uniformity of plasma process rate across the treated wafer surface. The process rate may be an etch rate or a deposition rate, for example.

Control of plasma ion density distribution within the chamber is essential in order to ensure uniformity of processing, or a uniform distribution of etch (or deposition) rate across the surface of the workpiece. The vacuum chamber is typically configured to have cylindrical symmetry. Plasma may be generated in the chamber by coupling RF source power to a ceiling electrode of the chamber. To optimize uniformity of plasma ion distribution, it is essential to deliver RF power to the ceiling electrode in a uniform symmetrical manner.

Typically, the ceiling electrode is also a gas distribution plate, requiring the inclusion within the ceiling electrode of various grounded components, such as gas supply conduits, coolant supply conduits and A.C. power lines for internal heaters. Because RF source power typically is applied directly to the ceiling electrode, there is a large voltage difference between the ceiling electrode and the grounded components within it, leading to a significant risk of arcing.

Another problem is that the presence within the ceiling electrode of grounded components, such as gas supply conduits, coolant supply conduits and A.C. power lines for heaters, may produce non-uniformities in the delivery of RF power to the bottom surface of the ceiling electrode.

What is need is a way of delivering RF power to the ceiling electrode in a manner that is unaffected by the presence of internal components within the ceiling electrode, and which does not produce a large voltage difference between the ceiling electrode and the grounded components inside the ceiling electrode.

### SUMMARY

In accordance with a first embodiment, a plasma reactor includes an RF power source, a vacuum chamber including a ceiling and a cylindrical side wall, a workpiece support pedestal in the chamber, and a ceiling electrode, the ceiling having an annular ceiling gap surrounding the ceiling electrode. The reactor further includes an RF coupling chamber. The RF coupling chamber includes (a) hollow inner, intermediate and outer conductive cylinders coaxial with the ceiling electrode and defining an outer annular volume overlying the annular ceiling gap, and an inner annular volume, the hollow inner conductive cylinder having a bottom end contacting the ceiling electrode; (b) a conductive top disk overlying the inner conductive cylinder and having a top disk peripheral annulus overlying the inner annular volume, the ceiling including an annular ceiling portion extending from about the inner conductive cylinder to the annular ceiling gap and underlying the inner annular volume, and a circular gap between the top disk peripheral annulus and the intermediate conductive cylinder; and (c) a coaxial power distributor coupling the RF power source to the intermediate conductive cylinder.

In one aspect, the coaxial power distributor includes: an axial center conductor having a top end connected to the RF power source and a bottom end; a conductive member extending radially from the bottom end of the axial center conductor; and plural axial conductive posts extending from the conductive member through the circular gap and to respective locations on the intermediate cylindrical conductor, the plural axial conductive posts being spaced apart. In a related aspect, the intermediate conductive cylinder extends axially from the ceiling toward the top disk peripheral annulus and is terminated at a top edge separated from the top disk peripheral annulus by the circular gap, the axial conductive posts connected to the top edge of the intermediate conductive cylinder.

In a further related aspect, the conductive member includes a disk-shaped plate. In another embodiment, the conductive member includes plural radial spokes.

The coupling chamber may further include a radial conduit formed as a shallow cylindrical volume partially enclosing the conductive member. The coaxial power distributor may further include an RF feeder outer conductor surrounding the axial center conductor and coupled to a return potential of the RF power source. The radial conduit may include: a conduit ceiling lying in a radial plane over the conductive member of the coaxial power distributor and having a center opening, the axial center conductor extending through the center opening of the conduit ceiling, the RF feeder outer conductor terminated at the center opening of the conduit ceiling; and a conduit floor including the top disk, the top disk including a top disk hole, the axial center conductor extending through the top disk hole.

The RF coupling chamber may further include a toroidal shaped ferrite ring coaxial with and between the inner and intermediate hollow cylindrical conductors.

In accordance with a second embodiment, a plasma reactor includes an RF power source, a vacuum chamber including a ceiling, a workplace support pedestal in the chamber, and a ceiling electrode, the ceiling having an annular ceiling gap surrounding the ceiling electrode. The plasma reactor further includes an RF coupling chamber including: (a) hollow inner and outer conductive cylinders coaxial with the ceiling electrode and defining between the inner and outer conductive cylinders an annular coupling chamber volume overlying the annular ceiling gap, the hollow inner conductive cylinder having a bottom end surrounding the ceiling electrode; (b) a conductive annular cap extending between and electrically contacting respective top edges of the inner and outer conductive cylinders; and (c) a coaxial power distributor connected between the RF power source and the hollow outer conductive cylinder.

In one aspect, the coaxial power distributor includes an axial center conductor having a top end connected to the RF power source and a bottom end, and plural respective spoke conductors electrically separate from the inner conductive cylinder and extending radially from the bottom end of the axial center conductor through the inner conductive cylinder to respective points on the outer conductive cylinder, the plural respective spoke conductors being spaced apart.

In a first aspect, there is a slit opening in the inner conductive cylinder, and the plural respective spoke conductors extend through the slit opening. In a second aspect, there are respective holes in the inner conductive cylinder, the plural respective spoke conductors extending through the respective holes.

The RF coupling chamber may further include a radial conduit formed as a shallow cylindrical volume partially enclosing the plural respective spokes. The coaxial power distributor further includes an RF feeder outer conductor surrounding a portion of the axial center conductor and coupled to a return potential of the RF power source. The radial conduit includes a conduit ceiling lying in a radial plane over the plural respective spokes and having a center opening, the axial center conductor extending through the center opening, the RF feeder outer conductor terminated at the center opening; and a conduit floor lying in a radial plane under the plural respective spokes, the conduit ceiling and conduit, floor terminated at the inner conductive cylinder, the floor including a floor opening, the axial center conductor extending through the floor opening,

In a further aspect, the RF coupling chamber further includes a toroidal shaped ferrite ring coaxial with and between the inner and outer hollow cylindrical conductors, and located between the annular cap and the coaxial power distributor.

### BRIEF DESCRIPTION OF THE DRAWINGS

So that the manner in which the exemplary embodiments of the present invention are attained and can be understood in detail, a more particular description of the invention, briefly summarised above, may be had by reference to the embodiments thereof which are illustrated in the appended drawings. It is to be appreciated that certain well known processes are not discussed herein in order to not obscure the invention.

FIG. 1 is a cut-away elevational view of a plasma reactor in accordance with a first embodiment.

FIG. 1A is a cross-sectional plan view taken along lines 1A-1A of FIG. 1.

FIG. 2 is a perspective view corresponding to FIG. 1.

FIG. 3 is a cross-sectional plan view taken along lines 3-3 of FIG. 1.

FIG. 4 is an enlarged view corresponding to FIG. 1.

FIG. 5 is a cut-away elevational view of a plasma reactor in accordance with a modification of the embodiment of FIG. 1.

FIG. 6 is a cut-away elevational view of a plasma reactor in accordance with a second embodiment.

FIG. 7 depicts a modification of the embodiment of FIG. 6, in which utility supply lines or conduits enter from a side location.

FIG. 8 depicts a modification employing plural radial conductive arms instead an RF power distribution plate.

FIG. 9 is a cut-away elevational view of a plasma reactor in accordance with a further modification of the embodiment of FIG. 6.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

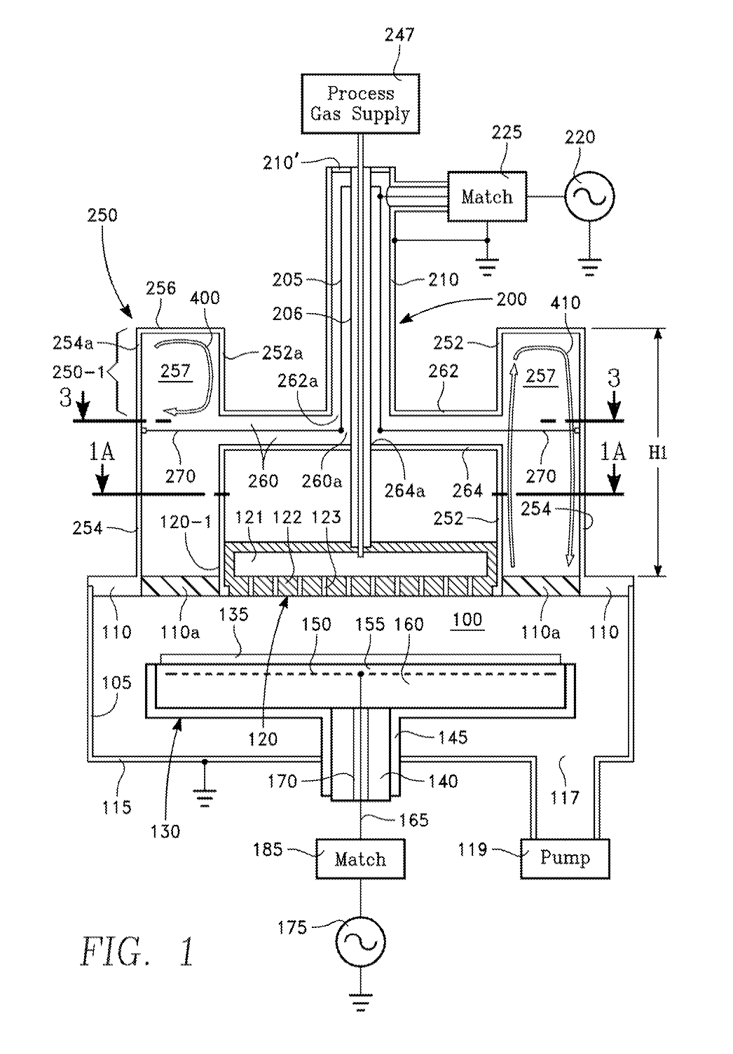

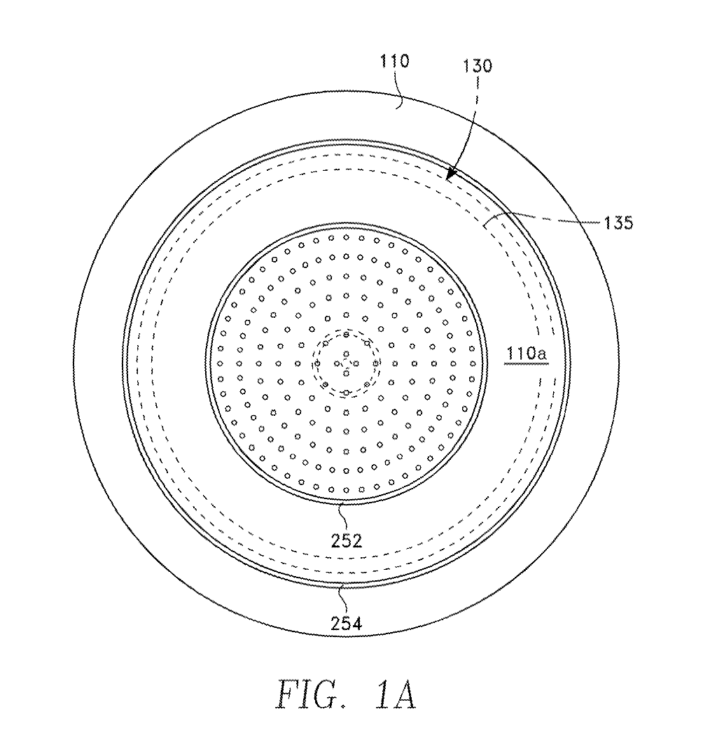

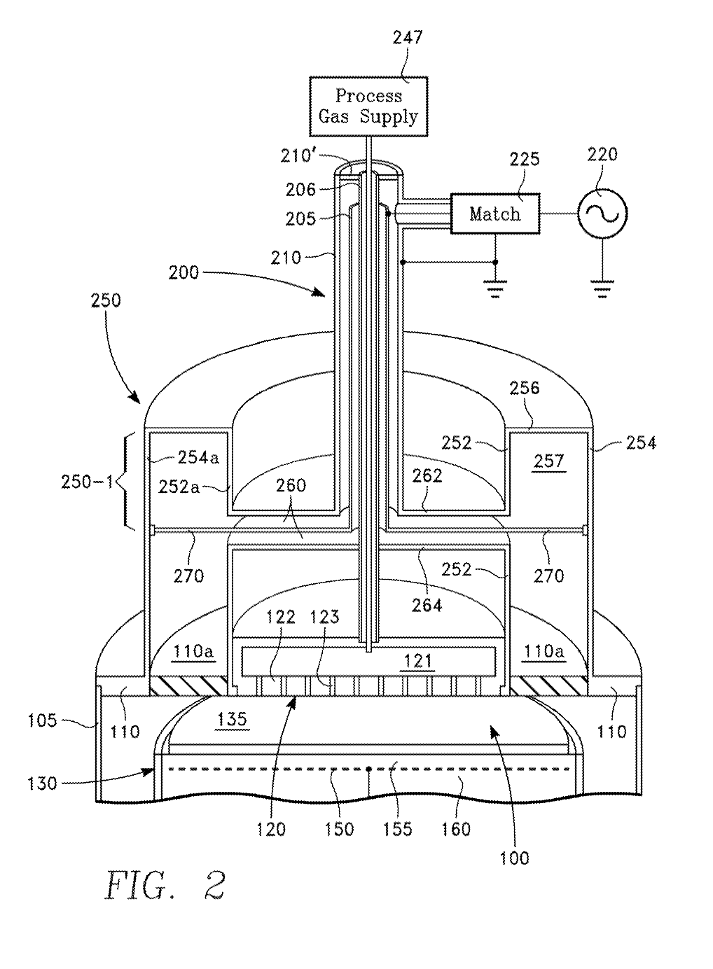

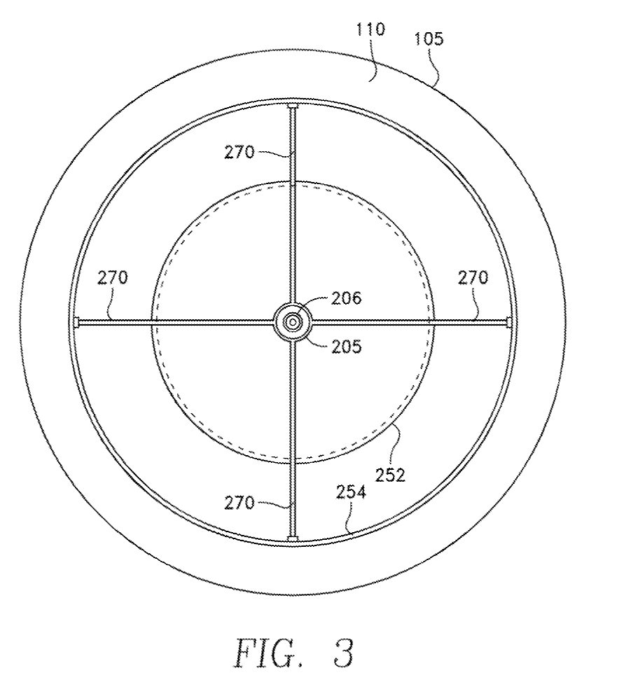

Referring to FIGS. 1, 1A, 2 and 3, a plasma reactor includes a vacuum chamber 100 enclosed by a cylindrical side wall 105, a ceiling 110 and a floor 115. The side wall 105 and floor 115 may be formed of metal and electrically grounded. The floor 115 has an opening or pumping port 117 through which a vacuum pump 119 is coupled, to the interior of the chamber 100. The ceiling 110 includes a gas distribution plate or showerhead 120 that functions as both a gas distributor and as a ceiling electrode and is referred to herein as the ceiling electrode 120. The ceiling 110 extends to the side wail 105, and includes an annular insulating section 110a surrounding the ceiling electrode. The ceiling electrode 120 is formed of a conductive material. The ceiling electrode 120 includes an interior gas manifold 121 and an underlying gas distribution layer 122 having an array of gas injection orifices 123. A workpiece support pedestal 130 is centered, within the chamber 100 to support a workpiece 135, such as a semiconductor wafer, in facing relationship with the showerhead 120. The pedestal 130 includes a center post 140 that extends through the floor 115. An electrically grounded outer layer 145 may enclose the pedestal 130 including the post 140. An insulated cathode electrode 150 is covered by a top insulating layer 155 and an underlying insulating bed 160. RF bias power is supplied to the cathode electrode 150 through a center conductor 165. The center conductor 165 may be separated from the grounded outer layer 145 by a coaxial insulating layer 170. The center conductor 165 may be coupled to an RF bias power generator 175 through an RF impedance match circuit 185.

A coaxial RF feeder 200 has a hollow center conductor 205 and a grounded outer conductor 210. A utility conduit 206 may extend coaxially through the hollow center conductor 205 while being insulated from the center conductor 205. As shown in FIG. 1, the utility conduit 206 is physically connected to the grounded outer conductor 210 at the top of the grounded outer conductor 210 by a conductive annular cap 210′, to provide a field-free region for the utility supply lines entering the conduit 206. An RF generator 220 supplying plasma source power is coupled to the center conductor 205. Optionally, the RF generator may be coupled to the center conductor 205 through an RF impedance match circuit 225. The chassis ground of the RF impedance match circuit 225 (or of the RF generator 220 in absence of the impedance match circuit 225) is connected to the outer conductor 210. RF power from the center conductor 205 is coupled to the ceiling electrode 120 in a manner which will be described below herein.

The utility conduit 206 within the center conductor 205 may contain one or more utility supply lines. For example, an outlet of a gas supply 247 is connected to gas flow lines inside and extending through the utility conduit 206. The utility conduit 206 may also contain other utility supply lines, such as electric power conductors to supply AC heaters (not illustrated) inside the ceiling electrode 120. Optionally, all of these utility supply lines may be fed through the hollow interior of the center conductor 205 without the utility conduit 206.

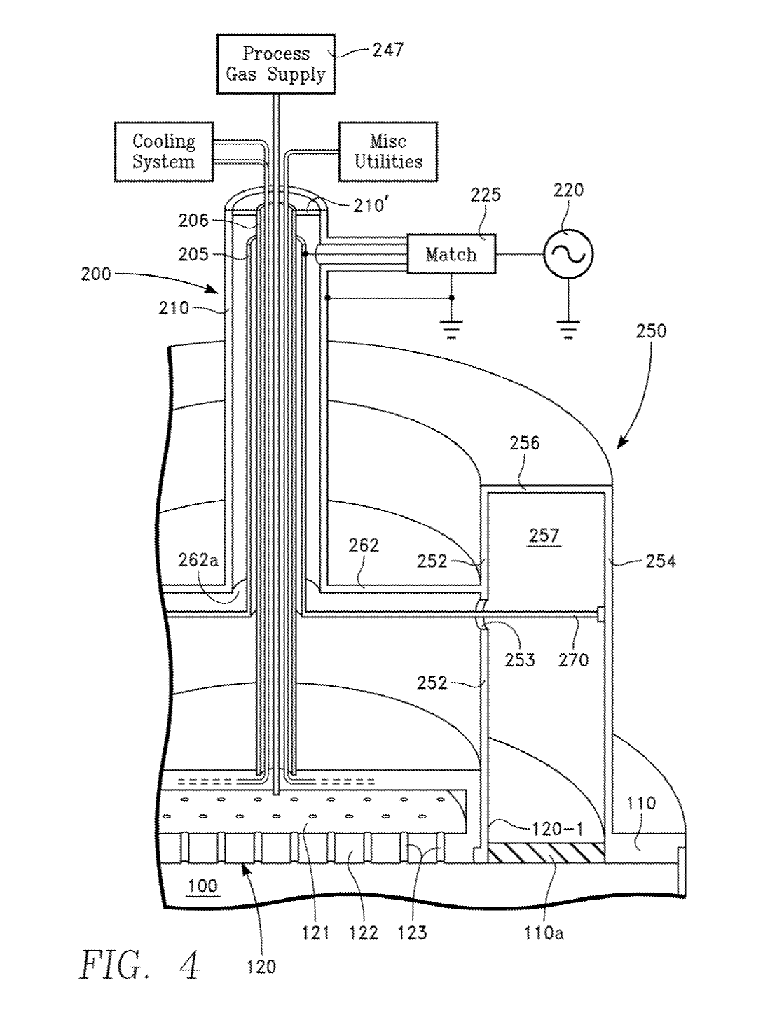

FIG. 4 is an enlarged view of the coaxial RF feeder 200, depicting in detail the connection of the RF output terminal of the impedance match 225 to the hollow center conductor 205, the disposition of the utility conduit 206 inside the hollow interior of the center conductor 205, and the disposition of utility supply lines, including process gas supply lines, inside the hollow utility conduit 206. In addition, FIG. 4 depicts an alternative mode, in which the radial spokes 270 extend through individual holes 253 in the inner coaxial wall 252, while not electrically contacting the inner coaxial wail 252.

Referring again to FIGS. 1, 1A, 2 and 3, an RF coupling chamber 250 couples RF power from the center conductor 205 to the ceiling electrode 120. The RF coupling chamber 250 includes inner and outer coaxial wails 252, 254 and an annular top 256, enclosing a coupling chamber annular volume 257. The RF coupling chamber 250 is sealed at its bottom by the annular insulating section 110a of the ceiling 110. Unless otherwise noted, the elements of the RF coupling chamber 250, other than the annular insulating section 110a, are formed of a metal such as aluminum. The RF coupling chamber 250 is coaxial with the coaxial RF feeder 200. The coupling chamber annular volume 257 generally is radially outside a circumferential edge 120-1 of the ceiling electrode 120. The coupling chamber annular volume 257 extends above the ceiling 110. The bottom of the inner coaxial wail 252 surrounds or encloses the ceiling electrode 120.

A shallow cylindrical hollow volume 260 (hereinafter referred to as a radial conduit 260) is enclosed by a disk-shaped conduit ceiling 262 and a disk-shaped conduit floor 264. The conduit ceiling 262 has a central opening 262a connected to and terminating the grounded outer conductor 210 of the coaxial RF feeder 200. Generally, the central opening is of the same diameter as the outer conductor 210. The center conductor 205 of the coaxial RF feeder 200 extends axially to and terminates at a center point 260a of the radial conduit 260. Plural spokes 270 within the interior of the radial conduit 260 lie in the plane of the center point 260a and extend radially outwardly from the center conductor 205 to the outer coaxial wail 254 through respective openings 253 in the inner coaxial wall 252. The plural spokes 270 are angularly spaced at even intervals and electrically contact the outer coaxial wall 254 at uniformly spaced contact points. The assembly including the plural spokes 270 and the center conductor 205 may be referred to as a coaxial power distributor.

The utility conduit 206 emerges from the bottom end of the hollow center conductor 205 and extends below the radial conduit 260 through a hole 264a in the conduit floor 264, and reaches the gas manifold 121 of the gas distribution plate 120. Various utility supply lines contained in the utility conduit 206, such as process gas supply line, coolant supply lines and electrical supply lines, make connection to suitable connection ports on or in the gas distribution plate 120. The region through which the utility lines extend from the bottom end of the center conductor 205 to the ceiling electrode 110 is enclosed by the inner coaxial wall 252 and is free of electric or RF fields.

The region of the RF coupling chamber 250 lying above the radial spokes 270 may be referred to as a primary sub-chamber 250-1. The primary sub-chamber 250-1 is the volume enclosed by upper portion 252a of the inner wall 252, upper portion 254a of the outer wail 254, the annular top 256 and the radial spokes 270.

Coupling of RF power from the center conductor 205 to the ceiling electrode 120 occurs as follows: RF power from the center conductor 205 generates a first RF toroidal current loop 400 flowing on the interior surfaces of the primary sub-chamber 250-1, namely the interior surfaces of the inner wall upper portion 252a, the outer wall upper portion 254a, the annular top 256 and the radial spokes 270. The first RF toroidal current loop 400 functions as a primary transformer winding. The first RF toroidal current loop induces a second RF toroidal current loop 410 flowing on interior surfaces of the entire length (height) of the RF coupling chamber 250. The second RF toroidal current loop 410 functions as a secondary transformer winding. The entire RF coupling chamber 250 therefore may be referred to as a secondary chamber containing the secondary winding or second RF current loop 410.

The uniformity of azimuthal distribution of the second toroidal RF current loop 410 determines the uniformity of RF power distribution on the ceiling electrode 120. This uniformity depends upon the uniformity or symmetry of the shape of the RF coupling chamber 250. The RF coupling chamber is perfectly symmetrical relative to the cylindrical axis of symmetry of the reactor of FIG. 1, so that RF power distribution on the ceiling electrode is at least nearly perfectly symmetrical.

The utility conduit 206 (and the various utility supply lines within the center conductor 205) is grounded, and its attachment to the ceiling electrode 120 holds the D.C. potential of the ceiling electrode 120 at ground. However, the second RF current loop 410 produces an RF potential on the ceiling electrode 120 of a high RF voltage, in accordance with the output power level of the RF generator 220, while allowing the ceiling electrode 120 to remain at D.C. ground.

The electrical length of the RF coupling chamber 250 (along the cylindrical axis of symmetry) need not necessarily be sufficient to be a resonant length. However, in one implementation, it is resonant or nearly resonant at the frequency of the RF generator 220. For resonance, the electrical length of the RF coupling chamber 250 may be a selected fraction of the wavelength of the RF voltage supplied by the RF generator 220, such as a quarter wavelength or a half wavelength, for example. The physical height H1 of the RF coupling chamber 250 above the ceiling may be less than this length, if desired.

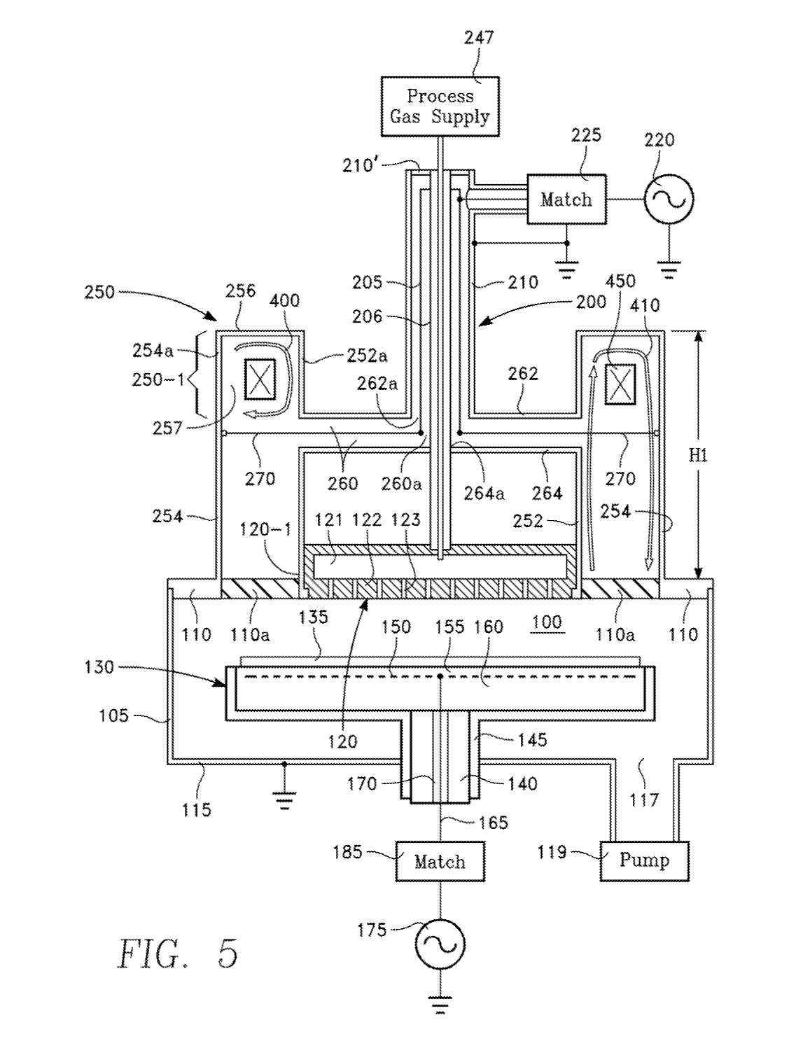

While the physical length of the RF coupling chamber 250 should be a fraction of the wavelength of the RF generator 220, such as a quarter wavelength, such a size occupies a significant amount of space, which may be scarce in a crowded production environment. FIG. 5 depicts a modification of the embodiment of FIG. 1, in which the electrical length of the RF coupling chamber 250 is increased without increasing its height HI above the ceiling 110. As shown in FIG. 5, the electrical length is increased by adding a toroidal ferrite 450 (or equivalent magnetically permeable element) in the center of the primary sub-chamber 250-1, and concentric with the cylindrical axis of symmetry of the chamber 100. Because the addition of the toroidal ferrite 450 provides a longer electrical length of the RF coupling chamber 250 for a given physical length, the physical length (and therefore the height H1) may be decreased to be less than the required electrical length (e.g., a quarter or half wavelength or full wavelength) while the electrical length meets the required fraction of the wavelength. If for example the frequency of the RF generator is about 220 MHz, the wavelength is about 1.25 meters. If it is desired that the length of the RF coupling chamber 250 be a half wavelength (for example), then its physical length (height H1) would have to be one half of 1.25 meters. However, by adding the toroidal ferrite 450 as shown in FIG. 5, the physical height HI may be reduced to a significantly shorter length while meeting the requirement of an effective length of half a wavelength. The reduction in length may be in a range of 5%-20%, depending upon the magnetic properties of the toroidal ferrite 450.

The ceiling electrode 120 is of the same diameter as the inner coaxial wall 252. The interior volume enclosed by the inner coaxial wail 252 between the annular cap 256 and the ceiling electrode, as well as the interior of the ceiling electrode 120, is free of electromagnetic fields. At the same time, the ceiling electrode 120 is at D.C. ground potential. The utility conduit 206 and/or the utility supply lines with the utility conduit are grounded and are electrically connected to the ceiling electrode 120, holding the ceiling electrode at D.C. ground potential. RF current flow on the ceiling electrode 120 occurs on its exterior surfaces only. The foregoing features prevent undesirable interactions between RF fields and the utility conduit 206 or any other utility supply lines (e.g., creation of non-uniformities in electric field distribution, arcing and the like).

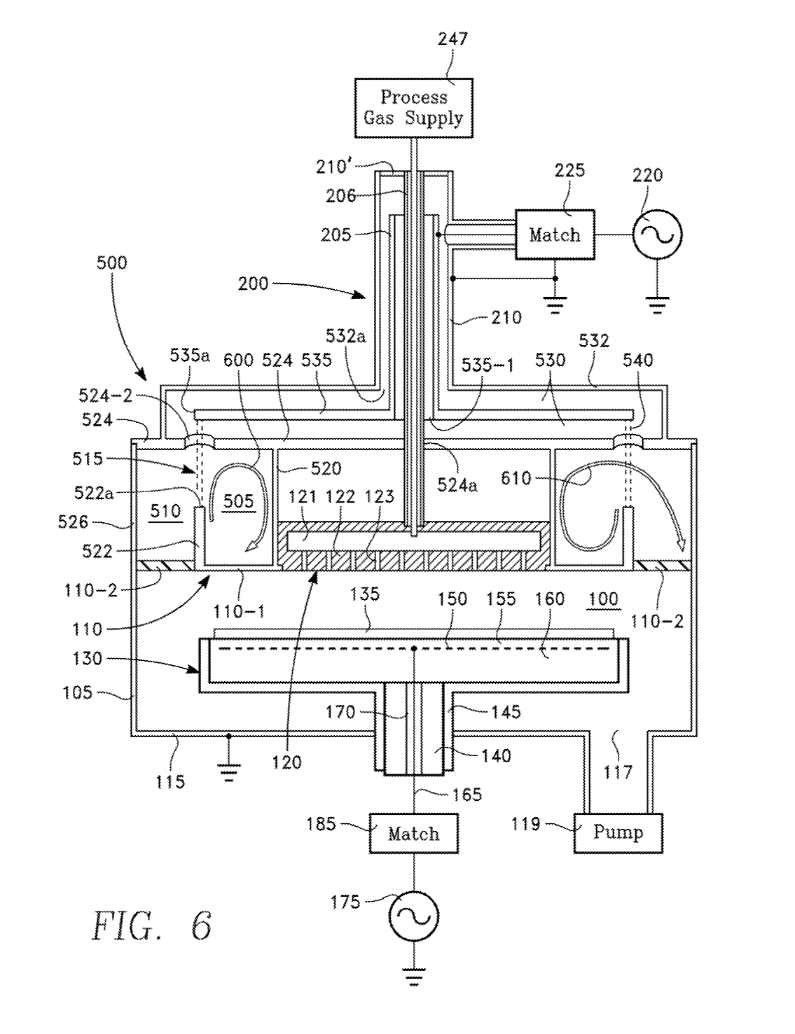

FIG. 6 depicts a plasma reactor having a folded RF coupling chamber 500, which is a folded version of the RF coupling chamber 250 of FIG. 1. The folded RF coupling chamber 500 can have the same electrical length as the RF coupling chamber 250 of FIG. 1, but only about one half the height. Unless otherwise noted, the elements of the folded RF coupling chamber 500 are formed of a suitable metal, such as aluminum.

In the embodiment of FIG. 6, as in the embodiment of FIG. 1, the plasma reactor includes a vacuum chamber 100 enclosed by a cylindrical side wall 105, a ceiling 110 and a floor 115. The side wall 105 and floor 115 may be formed of metal and electrically grounded. The floor 115 has an opening or pumping port 117 through which a vacuum pump 119 is coupled to the interior of the chamber 100. The ceiling 110 includes a gas distribution plate or showerhead 120 that functions as both a gas distributor and as a ceiling electrode and may be referred to as the ceiling electrode 120. The ceiling electrode or showerhead 120 is formed of a conductive material. The ceiling electrode 120 includes an interior gas manifold 121 and an underlying gas distribution layer 122 having an array of gas injection orifices 123. A workplace support pedestal 130 is centered within the chamber 100 to support a workpiece 135, such as a semiconductor wafer, in facing relationship with the showerhead 120. The pedestal 130 includes a center post 140 that extends through the floor 115. An electrically grounded outer layer 145 may enclose the pedestal 130 including the post 140. An insulated cathode electrode 150 is covered by a top insulating layer 155 and an underlying insulating bed 160. RF bias power is supplied to the cathode electrode 150 through a center conductor 165. The center conductor 165 may be separated from the grounded outer layer 145 by a coaxial insulating layer 170. The center conductor 165 may be coupled to an RF bias power generator 175 through an RF impedance match circuit 185.

In the embodiment of FIG. 6, as in the embodiment of FIG. 1, a coaxial RF feeder 200 has a hollow center conductor 205 and a grounded outer conductor 210. A utility conduit 206 extends coaxially through the hollow center conductor 205 while being insulated from the center conductor 205. An RF generator 220 supplying plasma source power is coupled to the center conductor 205 through an optional RF impedance match circuit 225. The chassis ground of the RF impedance match circuit 225 (or of the RF generator 220) is connected to the outer conductor 210. RF power from the bottom end of the center conductor 205 is coupled to the ceiling electrode 120 in a manner which will be described below herein. An outlet of a gas supply 247 is connected to gas flow lines inside and extending through the utility conduit 206. The utility conduit may also contain other utility lines, such as electric power conductors to supply AC heaters (not illustrated) inside the ceiling electrode 120.

The folded RF coupling chamber 500 of FIG. 6 consists of an inner annular chamber 505 and an outer annular chamber 510 with an opening 515 between them. The inner annular chamber 505 is enclosed by inner and intermediate coaxial walls 520, 522, a top disk 524 and an annular portion 110-1 of the ceiling 110. The outer annular chamber 510 is enclosed by the intermediate coaxial wall 522, an outer coaxial side wall 526 and by the top disk 524. The outer annular chamber 510 is enclosed at its bottom by an annular insulating section 110-2 of the ceiling 110. The inner coaxial wall 520 surrounds or encloses the ceiling electrode 120, and therefore the inner annular chamber 505 and the outer annular chamber 510 are radially outside of the ceiling electrode 120.

A radial conduit 530 is a shallow cylindrical volume coaxial with the inner and outer chambers 505 and 510, and is enclosed by a disk-shaped conduit ceiling 532 and by a floor formed by the disk-shaped, top 524. The conduit ceiling 532 has a central opening 532a connected to and terminating the grounded outer conductor 210 of the coaxial RF feeder 200. The central opening 532a and the outer conductor 210 generally are of the same diameter. A disk-shaped RF distribution plate 535 is disposed within the interior of the radial conduit 530 and has a peripheral edge 535a. The center conductor 205 of the coaxial RF1 feeder 200 extends through the central opening 532a of the conduit ceiling 532, and is connected to the center of the RF distribution plate 535. The center conductor 205 is electrically separated from the conduit ceiling 532. Plural axial posts 540 extend from the RF distribution plate 535 to a top annular edge 522a of the intermediate wail 522, through respective openings 524-2 in the disk-shaped top 524, each opening 524-2 accommodating a respective one of the axial posts 540. Each opening 524-2 is of a sufficient diameter so that the corresponding axial post 540 does not electrically contact the disk-shaped top 524. The plural posts 540 are angularly spaced at even intervals and electrically contact the intermediate wall 522 at uniformly spaced contact points.

The assembly including the RF distribution plate 535, the center conductor 205 and the plural axial posts 540 may be referred to as a coaxial power distributor.

The utility conduit 206 emerges from the bottom end of the hollow center conductor 205, extends through a central opening 535-1 in the RF distribution plate 535, and through an opening 524a. in the disk-shaped top 524, and continues toward the gas distribution plate 120. Various utility supply lines contained in the utility conduit 206, such as process gas supply line, coolant supply lines and electrical supply lines, make connection to suitable connection ports on or in the gas distribution plate 120. The region through which the utility lines extend past or below the bottom end of the center conductor 205 is enclosed by the inner coaxial wall 520 and is free of electric or RF fields.

The ceiling electrode 120 is of the same diameter as the inner coaxial wall 520. The interior volume enclosed by the inner coaxial wall 520, as well as the interior of the ceiling electrode 120, is free of electromagnetic fields. At the same time, the ceiling electrode 120 is at D.C. ground potential. The utility conduit 206 and/or the utility supply lines with the utility conduit are grounded and are electrically connected to the ceiling electrode 120, holding the ceiling electrode at D.C. ground potential. RF current flow on the ceiling electrode 120 occurs on its exterior surfaces only. The foregoing features prevent undesirable interactions between RF fields and the utility conduit 206 or any other utility supply lines (e.g., creation of non-uniformities in electric field distribution, arcing and the like).

With the folded RF coupling chamber 500 of FIG. 6, coupling of RF power from the center conductor 205 to the ceiling electrode 120 occurs as follows: RF power from the center conductor 205 generates a first RF toroidal current loop 600 flowing on the interior surfaces of the inner annular chamber 505. The first RF toroidal current loop 600 functions as a primary transformer winding. The first RF toroidal current loop 600 induces a second RF toroidal current loop 610 flowing on interior surfaces of the both the inner and outer annular chambers 505 and 510. The second RF toroidal current loop 610 functions as a secondary transformer winding. As indicated in FIG. 6, the second RF toroidal current loop 610 begins in the inner annular chamber 505 and extends in a spiral path indicated in the drawing through the opening 515 into the outer annular chamber 510.

The uniformity of azimuthal distribution of the toroidal RF current loops 600 and 610 determines the uniformity of RF power distribution on the ceiling electrode 120. This uniformity depends upon the uniformity or symmetry of the shape of the folded RF coupling chamber 500. The folded RF coupling chamber 500 is perfectly symmetrical relative to the cylindrical axis of symmetry of the reactor of FIG. 1, so that RF power distribution on the ceiling electrode 120 is at least nearly perfectly symmetrical.

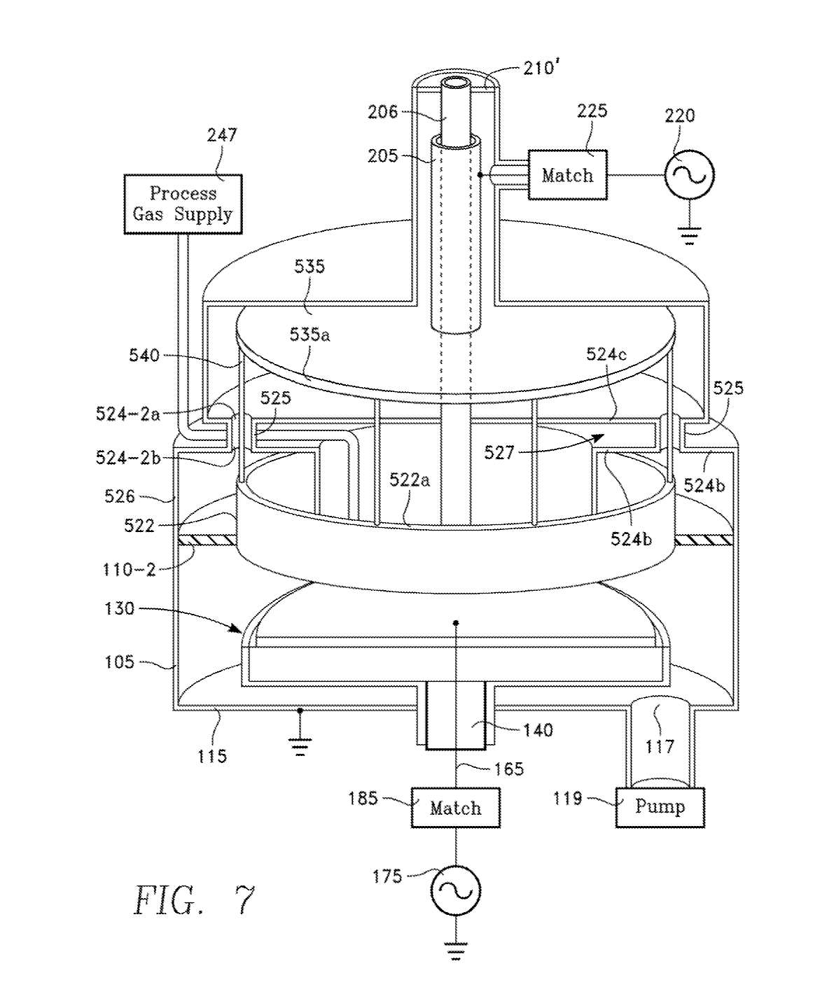

FIG. 7 depicts a variation of the embodiment of FIG. 6, in which utility supply lines or conduits (gas supply conduits, coolant supply conduits, electrical supply lines for heating, as some examples) enter through the side of the coupling chamber. For this purpose, the disk-shaped top 524 of FIG, 6 is divided into top and bottom planar disks 524c and 524b, respectively. The top and bottom planar disks are separated by a void 527. Respective hollow conduits 525 extend between respective holes 524-2a and 524-2b formed in the top and bottom planar disks 524c, 524b, respectively. Respective ones of the axial posts 540 extend through respective ones of the hollow conduits 525. The utility supply conduits or lines access the gas distribution plate 120 through the void 527 along a radial path, as depicted in FIG. 7.

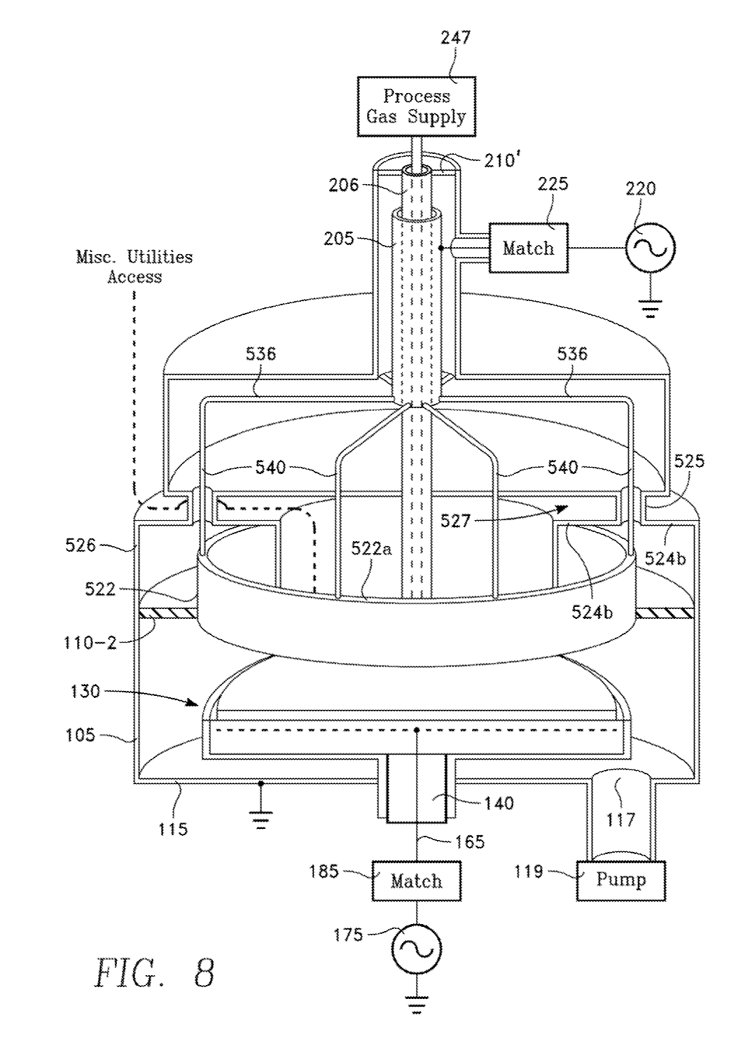

FIG. 8 depicts a modification applicable to either the embodiment of FIG. 6 or FIG, 7, in which the RF power distribution plate 535 is replaced by plural radial spokes 536. All of the spokes 536 are connected to the end of the center conductor 205 and radiate outwardly to the top ends of respective ones of the posts 540. The spokes 536 are angularly spaced at uniform intervals.

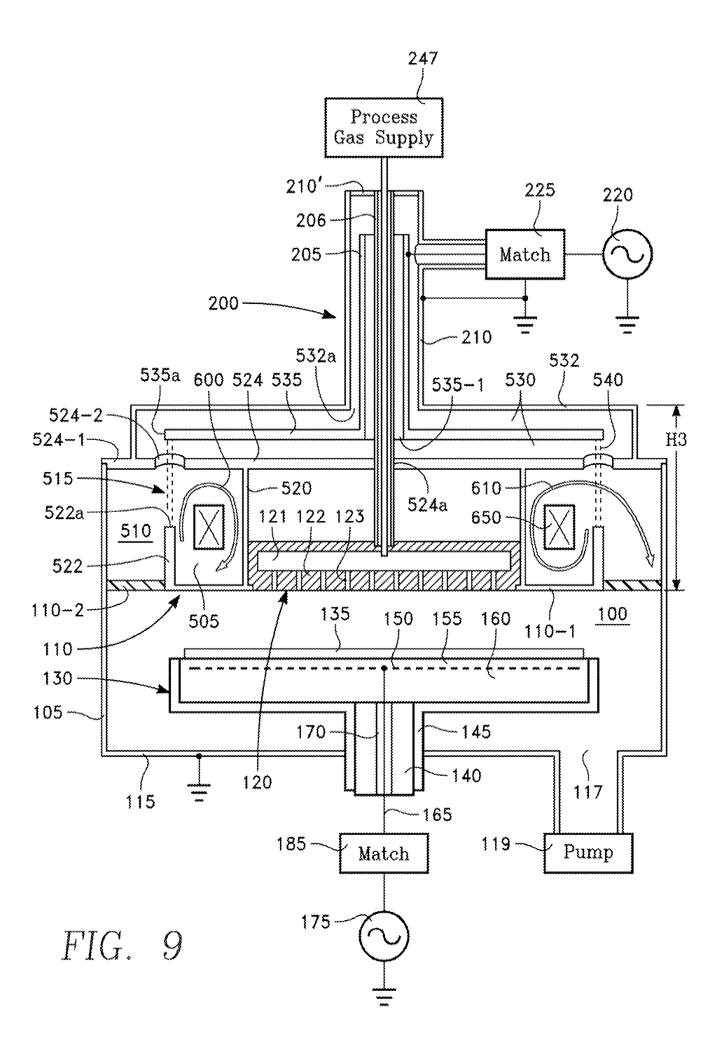

FIG. 9 depicts an embodiment in which the axial length (height) of the folded RF coupling chamber 500 can be further reduced without reducing its electrical length. For resonances, the electrical length of the folded RF coupling chamber 500 should be a fraction of the wavelength of the RF generator 220, such as a quarter or half wavelength, or even a full wavelength. However, such a size occupies a significant amount of space, which may be scarce in a crowded production environment. The height of the folded RF coupling chamber 500 may be reduced, without changing its electrical characteristics, by adding a toroidal ferrite 650 (or equivalent magnetic element) in the center of the inner annular chamber 505 concentric with the cylindrical axis of symmetry of the chamber 100. Because the addition of the toroidal ferrite 650 provides a longer electrical length of the folded RF coupling chamber 500 for a given physical length E3, the physical length (height) H3 may be decreased to be less than the required electrical length while the electrical length meets the required fraction of the wavelength. The reduction in length may be in a range of 5%-20%, depending upon the magnetic properties of the toroidal ferrite 650.

While the foregoing is directed to embodiments of the present invention, other and further embodiments of the invention may be devised without departing from the basic scope thereof, and the scope thereof is determined by the claims that follow.

What is claimed is;

1. A plasma reactor comprising:
a vacuum chamber including a ceiling and a cylindrical side wail, a workpiece support pedestal in said chamber, and a ceiling electrode;
an RF power source;
a folded RF coupling chamber comprising:
(a) hollow inner, intermediate and outer conductive cylinders coaxial with said ceiling electrode and defining an outer annular volume, and an inner annular volume, said hollow inner conductive cylinder having a bottom end contacting said ceiling electrode;
(b) a conductive top disk overlying said inner and outer conductive cylinders, said ceiling comprising an annular ceiling portion underlying said inner annular volume, and an insulative annular portion underlying said outer annular volume;
(c) a coaxial power distributor coupling said RF power source to said intermediate conductive cylinder.

2. The plasma reactor of claim 1 wherein said top disk comprises plural openings, and wherein said coaxial power distributor comprises:
an axial center conductor having a top end connected to said RF power source and a bottom end;
a conductive member extending radially from said bottom end of said axial center conductor;
plural axial conductive posts extending from said conductive member through respective ones of said plural openings and to respective locations on said intermediate cylindrical conductor, said plural axial conductive posts being spaced apart.

3. The plasma reactor of claim 2 wherein said intermediate conductive cylinder extends axially from said ceiling toward said top disk and is terminated at a top edge, said, axial conductive posts connected to said top edge of said intermediate conductive cylinder.

4. The plasma reactor of claim 2 wherein said conductive member comprises a disk-shaped plate.

5. The plasma reactor of claim 2 wherein said conductive member comprises plural radial spokes.

6. The plasma reactor of claim 2 further comprising a radial conduit formed as a shallow cylindrical volume partially enclosing said conductive member.

7. The plasma reactor of claim 6 wherein said coaxial power distributor further comprises:
an RF feeder outer conductor surrounding said axial center conductor and coupled to a return potential of said RF power source.

8. The plasma reactor of claim 7 wherein said radial conduit comprises:
a conduit ceiling lying in a radial plane over said conductive member of said coaxial power distributor and having a center opening, said axial center conductor extending through said center opening of said conduit ceiling, said RF feeder outer conductor terminated at said center opening of said conduit ceiling;
a conduit floor comprising said top disk, said top disk comprising a top disk hole, said axial center conductor extending through said top disk hole.

9. The plasma reactor of claim 8 wherein said RF power source comprises an RF power generator.

10. The plasma reactor of claim 9 wherein said RF power source further comprises an RF impedance match.

11. The plasma reactor of claim 8 wherein said ceiling electrode comprises a gas distribution plate, said plasma reactor further comprising plural utility supply lines extending through said coaxial RF feeder, through the interior of said inner conductive cylinder and to said gas distribution plate.

12. The plasma reactor of claim 1 further comprising a toroidal shaped ferrite ring coaxial with and between said inner and intermediate hollow cylindrical conductors.

13. The plasma reactor of claim 2 wherein said conductive top disk comprises upper and lower coaxial disks separated by a gap, and plural conduits in said gap enclosing respective ones of said axial conductive posts, and at least one utility supply line extending radially through said gap to said gas distribution plate.

14. A plasma reactor comprising:
a vacuum chamber including a ceiling and a side wall, a workpiece support pedestal in said chamber, and a ceiling, said ceiling comprising a ceiling electrode;
an RF power scarce;
an RF coupling chamber comprising:
(a) hollow inner and outer conductive cylinders coaxial with said ceiling electrode and defining between said inner and outer conductive cylinders an annular coupling chamber volume, said hollow inner conductive cylinder having a bottom end surrounding said ceiling electrode, said ceiling comprising an insulating annulus underlying said annular coupling chamber volume;
(b) a conductive annular cap extending between and electrically contacting respective top edges of said inner and outer conductive cylinders;
(c) a coaxial power distributor connected between said RF power source and said hollow outer conductive cylinder.

15. The plasma reactor of claim 14 wherein said coaxial power distributor comprises:
an axial center conductor having a top end connected to said RF power source and a bottom end;
plural respective spoke conductors electrically separate from said inner conductive cylinder and extending radially from said bottom end of said axial center conductor through said inner conductive cylinder to respective points on said outer conductive cylinder, said plural respective spoke conductors being spaced apart.

16. The plasma reactor of claim 15 further comprising respective holes in said inner conductive cylinder, said plural respective spoke conductors extending through said respective holes.

17. The plasma reactor of claim 15 further comprising a slit opening in said inner conductive cylinder, said plural respective spoke conductors extending through said slit opening in said inner conductive cylinder.

18. The plasma reactor of claim 15 further comprising a radial conduit formed as a shallow cylindrical volume partially enclosing said plural respective spokes.

19. The plasma reactor of claim 18 wherein said coaxial power distributor further comprises:
an RF feeder outer conductor surrounding a portion of said axial center conductor and coupled to a return potential of said RF power source.

20. The plasma reactor of claim 19 wherein said radial conduit comprises:
a conduit ceiling lying in a radial plane over said plural respective spokes and having a center opening, said axial center conductor extending through said center opening, said RF feeder outer conductor terminated at said center opening;
a conduit floor lying in a radial plane under said plural respective spokes, said conduit ceiling and conduit floor terminated at said inner conductive cylinder, said floor comprising a floor opening, said axial center conductor extending through said floor opening.
